(19) United States
(12) Patent Application Publication
(10) Pub. No.: US 2025/0379137 A1
(43) Pub. Date: Dec. 11, 2025

(54) EMBEDDED EXPOSED LID

(71) Applicant: QUALCOMM Incorporated, San Diego, CA (US)

(72) Inventors: Wei YAO, Santa Clara, CA (US); Karthikeyan DHANDAPANI, San Diego, CA (US)

(21) Appl. No.: 18/734,672

(22) Filed: Jun. 5, 2024

(51) Int. Cl. H01L 23/498; H01L 23/00

(52) U.S. Cl. CPC H01L 23/49861; H01L 23/49816; H01L 23/49827; H01L 24/13; H01L 24/32; H01L 2224/13008; H01L 2224/32245; H01L 2924/3511

(57) ABSTRACT

In an aspect, an apparatus may include a lid and a package substrate. The package substrate may include a first metallization structure on a substrate core and an embedded lid support structure disposed on a perimeter of the first metallization structure in the package substrate. The lid is coupled to the substrate core through the embedded lid support structure.

### TECHNICAL FIELD

The present disclosure generally relates to semiconductor devices including an integrated circuit (IC) package, and more particularly, but not exclusively, to devices including substrates with an embedded exposed lid and fabrication techniques thereof.

### BACKGROUND

IC technology has achieved great strides in advancing computing power through miniaturization of electronic components. A semiconductor device generally referred to as an IC chip, an IC die, a chip or die may include a set of circuits integrated thereon. In some implementations, an IC device may be formed by incorporating and protecting one or more IC chips or dies in an IC package, where various power and signal nodes of the one or more IC chips can be electrically coupled to respective conductive terminals of the IC package via electrical paths formed in one or more package substrates of the IC package. The term “substrate” in this disclosure, unless otherwise specified, refers to a packaging substrate for packaging one or more dies into an IC package, which is different from the semiconductor substrate for forming a die.

Various packaging technologies can be found in many electronic devices, including processors, servers, radio frequency (RF) ICs, etc. Advanced packaging and processing techniques allow for complex devices, such as multi-die devices and system on a chip (SOC) devices, which may include multiple function blocks, with each function block designed to perform a specific function, such as, for example, a microprocessor function, a graphics processing unit (GPU) function, a communications function (e.g., Wi-Fi, Bluetooth, and other communications), and the like. As used herein the term “function block” should not be construed to be power or signal lines, traces, conductors, pads, etc. that merely function to transmit an electrical voltage and/or current.

As designs become more complex, package warpage control is critical to enable high yields during final integration into end devices, such as mounting/electrically coupling dies, package, interposers, surface mount technology (SMT) devices, SOC devices, motherboards/printed circuit boards (PCBs) and the like. Significant effort has been undertaken to change materials in the substrate, as well as mold compounds and use of external stiffeners/lids to control package warpage. As package footprints increase, and package thickness reduction continues, warpage control becomes more difficult.

Accordingly, there is a need for improved package substrates for semiconductor devices and methods of manufacturing the same to address the deficiencies in conventional designs, as disclosed herein.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

At least one aspect includes an apparatus comprising: a lid; a package substrate comprising: a first metallization structure; a substrate core; and an embedded lid support structure disposed on a perimeter of the first metallization structure, wherein the embedded lid support structure is configured to couple the lid to the substrate core.

At least one aspect includes a method of manufacturing an apparatus that includes forming a lid; forming a package substrate comprising: forming a first metallization structure on a substrate core; and forming an embedded lid support structure disposed on a perimeter of the first metallization structure; and coupling the lid to the substrate core through the embedded lid support structure.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1 illustrates a partial plan view of an apparatus, according to aspects of the disclosure.

FIG. 2 illustrates a partial plan view of an apparatus, according to aspects of the disclosure.

FIG. 3 is a partial cross-sectional view of an apparatus, according to aspects of the disclosure.

FIG. 4 is a partial cross-sectional view of an apparatus, according to aspects of the disclosure.

FIG. 5A illustrates a partial cross-sectional view of an apparatus 500, according to aspects of the disclosure.

FIG. 5B illustrates a partial plan view of the embedded lid support structure, according to aspects of the disclosure.

FIG. 6A is a partial cross-sectional view of an apparatus, according to aspects of the disclosure.

FIG. 6B illustrates a partial plan view of the embedded lid support structure, according to aspects of the disclosure.

FIG. 7 is a partial cross-sectional view of an apparatus, according to aspects of the disclosure.

FIG. 8 illustrates a method for manufacturing/fabricating and apparatus with an embedded exposed lid, according to aspects of the disclosure.

FIG. 9 illustrates a mobile device that may incorporate one or more IC devices and/or IC packages described herein, according to aspects of the disclosure.

FIG. 10 illustrates various electronic devices that may incorporate one or more IC devices and/or IC packages described herein, according to aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The terms “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage, or mode of operation.

The terminology used herein is for the purpose of describing particular aspects only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. Additionally, as used herein, terms such as about, approximately, generally, substantially in the range of, and the like indicate that the examples provided are not intended to be limited to the precise numerical values, geometric shapes, angles, etc. and include normal variations due to, manufacturing tolerances and variations, material variations, and other design considerations. Further, as used herein, terms such as top, bottom, above, below, first, last, front, back, adjacent, and the like indicate convenient indications of orientations, assemblies or arrangements of various elements in the examples provided and should not be construed as absolute orientations, assemblies or arrangements. The term “metallization structure” as used herein may include any configuration of metal layers, vias and dielectric layers. In some aspects, a metallization structure may function as a redistribution layer (RDL) structure, which may provide for metal interconnects that redistribute the access to different parts of the die and in some aspects may allow for a change in pitch between connectors to allow for easier connection from the die to external components.

In certain described example implementations, instances are identified where various component structures and portions of operations can be taken from known, conventional techniques, and then arranged in accordance with one or more aspects. In such instances, internal details of the known, conventional component structures and/or portions of operations may be omitted to help avoid potential obfuscation of the concepts illustrated in the illustrative aspects disclosed herein.

As noted in the foregoing, conventional designs do not adequately address warpage and thermal issues in semiconductor devices including substrates used in package substrates. In conventional mobile, computer, server, and auto processor packaging solutions, two type of lid designs are used, enclosed and exposed lids. The enclosed lid design can effectively control package warpage. However, due to usage of the thermal interface material, it has poor thermal dissipation. In contrast, the exposed lid design has much better thermal performance, but it causes excessive warpage that can lead to cold joint issue when attaching IC packages (e.g., including processors, other dies, etc.) to OEM boards. To meet the design specifications for warpage (e.g., Joint Electron Device Engineering Council (JEDEC)), the exposed lid must be very thick which generally will violate the board level assembly requirements.

The various aspects disclosed provide improved design options to control and improve warpage (e.g., Room Temperature Warpage (RTW) and High Temperature Warpage (HTW)) and improve thermal dissipation of the various semiconductor devices. As used herein the term “embedded exposed lid” is used to designate lids that are exposed but also include an embedded lid support structure (e.g., lid foot, dense via, etc.) to anchor the exposed lid to substrate core of the package substrate. Designs in accordance with the various aspects disclosed can meet JEDEC warpage specifications (e.g., JESD22-B112C) without increasing the IC package Z height. Further, the various aspects also provide improved thermal dissipation relative to conventional lid designs.

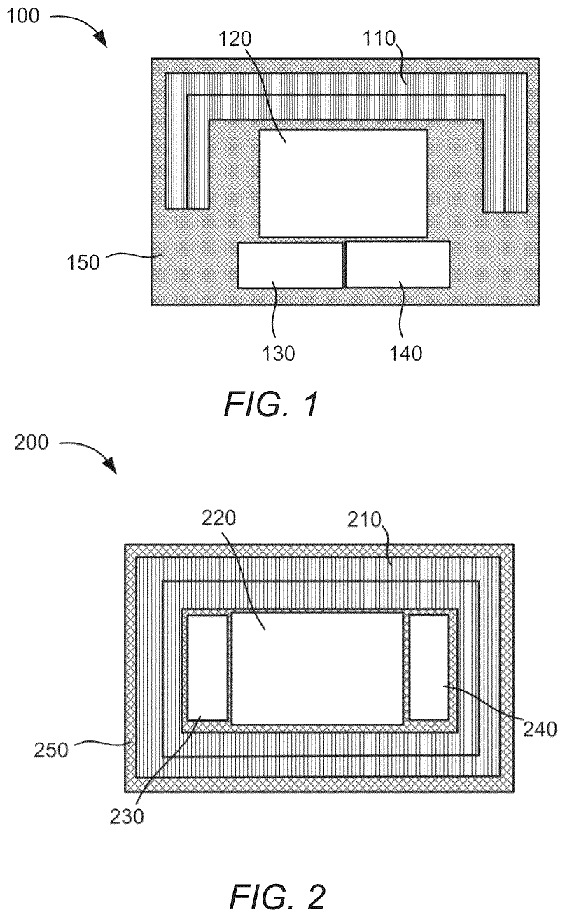

FIG. 1 illustrates a partial plan view of an apparatus 100, according to aspects of the disclosure. In some aspects, FIG. 1 is a simplified partial view of the apparatus 100, and certain details and components of the apparatus 100 may be simplified or omitted in FIG. 1. In some aspects, the apparatus 100 may be a portion of an IC package and/or a larger apparatus such as a mobile phone, server, etc.

As shown in FIG. 1, in some aspects, the apparatus 100 includes a die 120 (e.g. SOC, processor, etc.) disposed on a top surface of a package substrate 150. Additional dies 130 and 140 (e.g., memory, input/output circuits, wireless modems, filters, etc.) may optionally be disposed on and electrically coupled to the package substrate 150. An embedded exposed lid 110 is disposed may completely or at least partially enclose the die 120 (e.g., embedded half lid). The embedded exposed lid 110 is coupled to the package substrate 150 by an embedded lid support structure, which will be illustrated and described in detail in the following paragraphs. It will be appreciated that the various aspects disclosed and claimed herein should not be interpreted to be limited to the specific illustrated example configurations.

FIG. 2 illustrates a partial plan view of an apparatus 200, according to aspects of the disclosure. In some aspects, FIG. 2 is a simplified partial view of the apparatus 200, and certain details and components of the apparatus 200 may be simplified or omitted in FIG. 2. In some aspects, the apparatus 200 may be a portion of an IC package and/or a larger apparatus such as a mobile phone, server, etc.

As shown in FIG. 2, in some aspects, the apparatus 200 includes a die 220 (e.g., SOC, processor, etc.) disposed on a top surface of a package substrate 250. Additional dies 230 and 240 (e.g., memory, input/output circuits, wireless modems, filters, etc.) may optionally be disposed on and electrically coupled to the package substrate 150. An embedded exposed lid 210 may be disposed completely or at least partially enclose the die 220. In the illustrated example, the apparatus has embedded full lid (e.g., the lid encloses SOC/DRAM at all four sides). The embedded exposed lid 210 is coupled to the package substrate 250 by an embedded lid support structure, which will be illustrated and described in detail in the following paragraphs. It will be appreciated that the various aspects disclosed and claimed herein should not be interpreted to be limited to the specific example configurations illustrated and discussed.

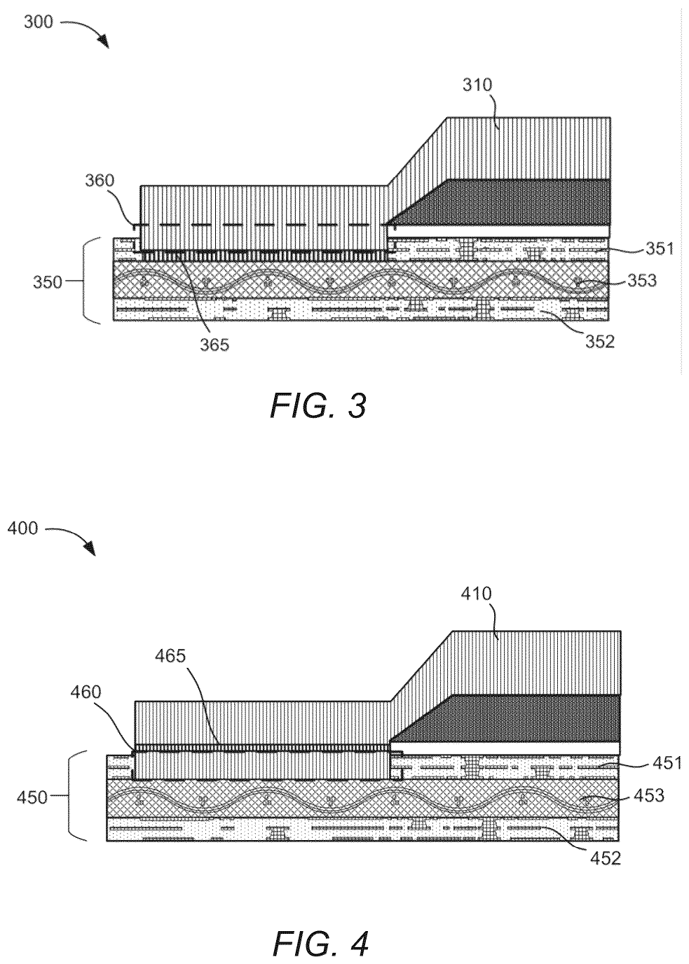

FIG. 3 illustrates a partial cross-sectional view of an apparatus 300, according to aspects of the disclosure. In some aspects, FIG. 3 is a simplified partial cross-sectional view of the apparatus 300, and certain details and components of the apparatus 300 may be simplified or omitted in FIG. 3. In some aspects, the apparatus 300 may be a portion of an IC package and/or a larger apparatus such as a mobile phone, server, etc.

As shown in FIG. 3, in some aspects, the apparatus 300 includes a lid 310 coupled to a package substrate 350. The package substrate includes a first metallization structure 351, a second metallization structure 352 and a substrate core 353. Additionally, an embedded lid support structure 360 is disposed on a perimeter of the first metallization structure 351. The embedded lid support structure 360 is configured to couple the lid 310 to the substrate core 353. As illustrated, the embedded lid support structure 360 is an extended foot portion of the lid 310 that is disposed in a cavity formed in the package substrate 350. In some aspects, the embedded lid support structure 360 is directly bonded to the substrate core 353 by a gel type adhesive 365 or any suitable bonding material. It will be appreciated that the cavity may be formed in the package substrate 350 during fabrication of the package substrate or may be formed in a separate operation post fabrication. It will be appreciated that the various aspects disclosed and claimed herein should not be interpreted to be limited to the specific example configurations illustrated and discussed.

FIG. 4 illustrates a partial cross-sectional view of an apparatus 400, according to aspects of the disclosure. In some aspects, FIG. 4 is a simplified partial cross-sectional view of the apparatus 400, and certain details and components of the apparatus 400 may be simplified or omitted in FIG. 4. In some aspects, the apparatus 400 may be a portion of an IC package and/or a larger apparatus such as a mobile phone, server, etc.

As shown in FIG. 4, in some aspects, the apparatus 400 includes a lid 410 coupled to a package substrate 450. The package substrate includes a first metallization structure 451, a second metallization structure 452 and a substrate core 453. Additionally, an embedded lid support structure 460 is disposed on a perimeter of the first metallization structure 451. The embedded lid support structure 460 is configured to couple the lid 410 to the substrate core 453. As illustrated, the embedded lid support structure 460 is a conductive block disposed above the substrate core 453 and in direct contact with the substrate core 453. In some aspects, the embedded lid support structure 460 (e.g., conductive block) is bonded to the lid with a compliance material (e.g., metallic adhesive or IMC) 465. In some aspects the conductive block may be a solid metal portion fabricated as part of the build-up of the first metallization structure 451 and the fabrication process of the package substrate 450. In other aspects, the conductive block may be fabricated in separate process, e.g., a cavity formed and filled with metal, etc. In some aspects, the conductive block has a surface area at the interface to lid 410 where the adhesive 465 is applied that is substantially the same as opposing surface of the lid 410. It will be appreciated that the various aspects disclosed and claimed herein should not be interpreted to be limited to the specific example configurations illustrated and discussed.

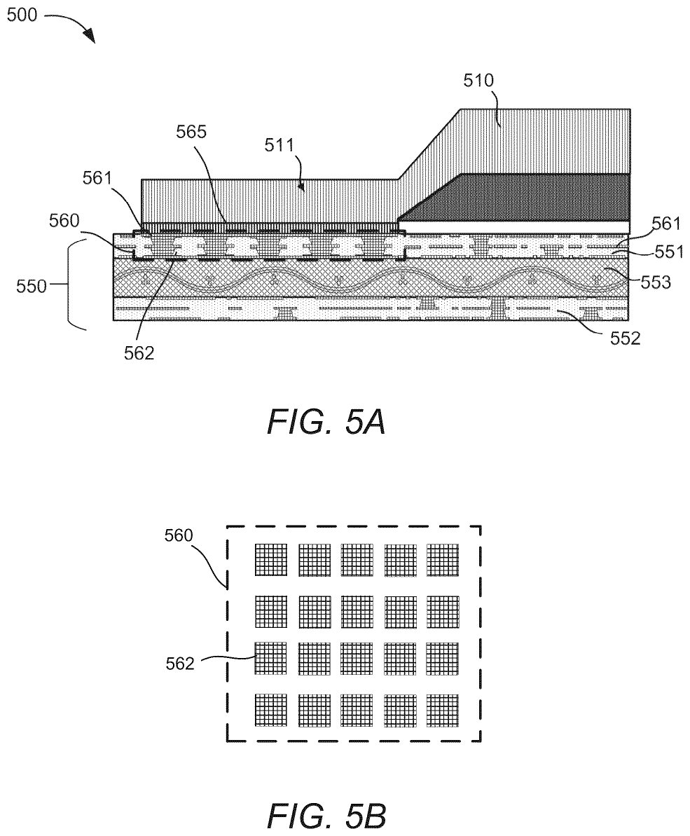

FIG. 5A illustrates a partial cross-sectional view of an apparatus 500, according to aspects of the disclosure. In some aspects, FIG. 5A is a simplified partial cross-sectional view of the apparatus 500, and certain details and components of the apparatus 500 may be simplified or omitted in FIG. 5A. In some aspects, the apparatus 500 may be a portion of an IC package and/or a larger apparatus such as a mobile phone, server, etc.

As shown in FIG. 5A, in some aspects, the apparatus 500 includes a lid 510 coupled to a package substrate 550. The package substrate includes a first metallization structure 551, a second metallization structure 552 and a substrate core 553. Additionally, an embedded lid support structure 560 is disposed on a perimeter of the first metallization structure 551. The embedded lid support structure 560 is configured to couple the lid 510 to the substrate core 553. As illustrated, the embedded lid support structure 560 includes a plurality of stacked vias 562 arranged in a stacked formation disposed above the substrate core 553 and in direct contact with the substrate core 553. It will be appreciated that the plurality of stacked vias 562 are design rule compliant (e.g., adhering to spacing, etc. rules) to provide support to the lid 510 and a strong coupling between the lid 510 and the substrate core 553. In some aspects, the embedded lid support structure 560 (e.g., stacked vias 562) is bonded to the lid with a compliance material (e.g., metallic adhesive or IMC) 565. In some aspects, the plurality of stacked vias 562 and plurality of metal layers 561 may be fabricated as part of the build-up of the first metallization structure 551 as part of the fabrication process of the package substrate 550. In some aspects, the top metal layer of the plurality of metal layers 561 has a surface area at the interface (e.g., lid foot) to the lid 510 where the compliance material 565 is applied that is substantially the same as opposing surface of the lid foot 511 of lid 510. Likewise, in some aspects, it will be appreciated that the plurality of stacked vias 562 extend to substantially cover a similar area, as the top metal layer, as illustrated. In some aspects, the plurality of stacked vias 562 may be directly bonded to the lid with a compliance material 565, without a top metal layer. It will be appreciated that the various aspects disclosed and claimed herein should not be interpreted to be limited to the specific example configurations illustrated and discussed.

FIG. 5B illustrates a partial plan view of the embedded lid support structure 560, according to aspects of the disclosure. As illustrated, in some aspects, the plurality of stacked vias 562 may be arranged in a series of rows and columns that provide for support for the lid 510 over an area that is substantially the same as opposing surface of the of the lid foot 511, as described above. In various aspects, the rows and columns may be uniform, staggered or random. In various aspects, a cross-section of the plurality of stacked vias 562 may have a rectangular, circular or other geometric shape. Accordingly, it will be appreciated that the various aspects disclosed and claimed herein should not be interpreted to be limited to the specific example configurations illustrated and discussed.

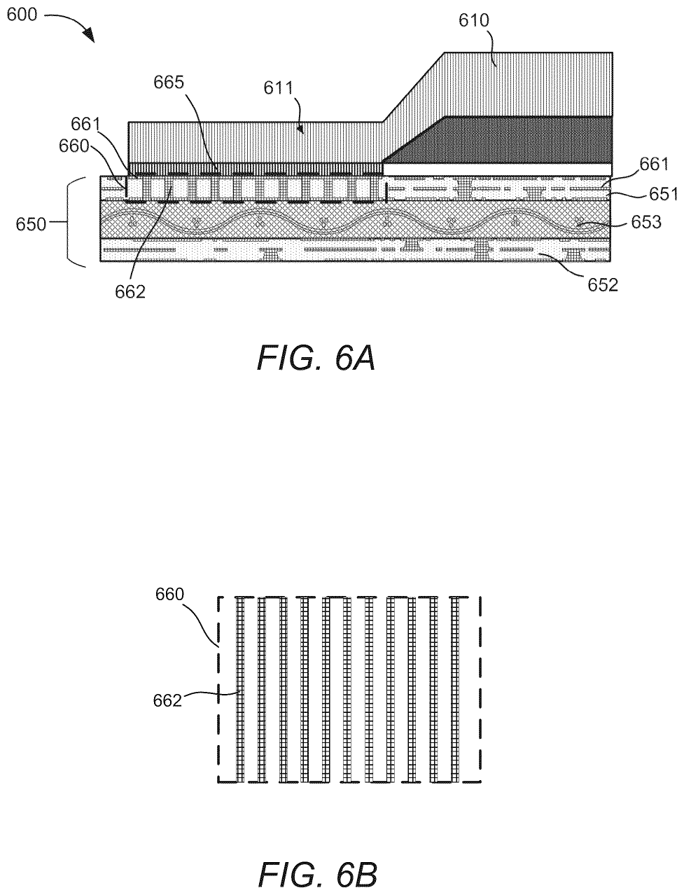

FIG. 6A illustrates a partial cross-sectional view of an apparatus 600, according to aspects of the disclosure. In some aspects, FIG. 6A is a simplified partial cross-sectional view of the apparatus 600, and certain details and components of the apparatus 600 may be simplified or omitted in FIG. 6A. In some aspects, the apparatus 600 may be a portion of an IC package and/or a larger apparatus such as a mobile phone, server, etc.

As shown in FIG. 6A, in some aspects, the apparatus 600 includes a lid 610 coupled to a package substrate 650. The package substrate includes a first metallization structure 651, a second metallization structure 652 and a substrate core 653. Additionally, an embedded lid support structure 660 is disposed on a perimeter of the first metallization structure 651. The embedded lid support structure 660 is configured to couple the lid 610 to the substrate core 653. As illustrated, the embedded lid support structure 660 includes a plurality of stacked traces 662 disposed above the substrate core 653 and in direct contact with the substrate core 653. It will be appreciated that the plurality of stacked traces 662 in a stacked formation that is design rule compliant to provide support to the lid 610 and a strong coupling between the lid 610 and the substrate core 653. In some aspects, the embedded lid support structure 660 (e.g., stacked traces 662) is bonded to the lid with a compliance material 665, which provides a stronger bond than conventional adhesives. In some aspects the compliance material comprises a metallic adhesive, solder or intermetallic compound (IMC), such as Cu₆Sn₅. In some aspects, the plurality of stacked traces 662 may be fabricated as part of the build-up of the first metallization structure 651 as part of the fabrication process of the package substrate 650. In some aspects, the top metal layer of the plurality of metal layers 661 has a surface area at the interface (e.g., lid foot) to the lid 610 where the compliance material 665 is applied that is substantially the same as opposing surface of the lid foot 611 of lid 610. Likewise, it will be appreciated that the plurality of stacked traces 662 extend to substantially cover a similar area, as the top metal layer, as illustrated. In some aspects, the plurality of stacked traces 662 may be directly bonded to the lid with a compliance material 665, without a top metal layer. It will be appreciated that the various aspects disclosed and claimed herein should not be interpreted to be limited to the specific example configurations illustrated and discussed.

FIG. 6B illustrates a partial plan view of the embedded lid support structure 660, according to aspects of the disclosure. As illustrated, in some aspects, the plurality of stacked traces 662 may be arranged in a series of columns or rows that provide for support for the lid 610 over an area that is substantially the same as opposing surface of the of the lid foot 611, as described above. In various aspects, the rows or columns may be uniform, staggered or randomly spaced. Accordingly, it will be appreciated that the various aspects disclosed and claimed herein should not be interpreted to be limited to the specific example configurations illustrated and discussed.

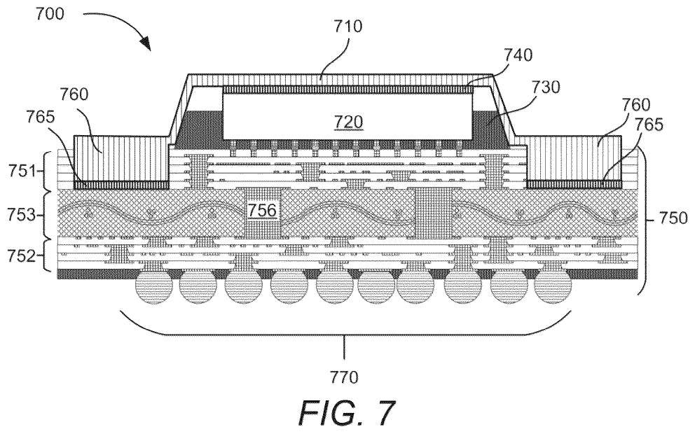

FIG. 7 illustrates a partial cross-sectional view of an apparatus 700, according to aspects of the disclosure. In some aspects, FIG. 7 is a simplified partial cross-sectional view of the apparatus 700, and certain details and components of the apparatus 700 may be simplified or omitted in FIG. 7. In some aspects, the apparatus 700 may be a portion of an IC package and/or a larger apparatus such as a mobile phone, server, etc.

As shown in FIG. 7, in some aspects, the apparatus 700 includes a lid 710 coupled to a package substrate 750. The package substrate includes a first metallization structure 751, a second metallization structure 752 and a substrate core 753. Additionally, an embedded lid support structure 760 is disposed on a perimeter of the first metallization structure 751. The embedded lid support structure 760 is configured to couple the lid 710 to the substrate core 753. As illustrated, similar to the configuration of FIG. 3, the embedded lid support structure 760 is an extended lid foot portion of the lid 710 that is disposed in a cavity formed in the package substrate 750. In some aspects, the embedded lid support structure 760 is directly bonded to the substrate core 753 by an adhesive 765 or any suitable bonding material. It will be appreciated that the cavity may be formed in the package substrate 750 during fabrication of the package substrate or may be formed in a separate operation post fabrication.

A die 720 is disposed on and electrically coupled to the first metallization structure of the package substrate 750. In some aspects an underfill 730 may optionally be provided. The underfill 730 is disposed between the die 720 and the top surface of the package substrate. In some aspects, the die 720 may be coupled to the lid 710 by an adhesive 740, which may provide mechanical and thermal coupling to the lid 710. In some aspects, a plurality of package connectors 770 are disposed on a bottom surface of the package substrate 750 and electrically coupled to the second metallization structure 752 of the package substrate 750. The package connectors 770 (e.g., solder balls, ball grid array (BGA), solder paste, copper pillars, etc.) are configured to electrically couple the package substrate 750 through the second metallization structure 752 to OEM boards, external components, devices, etc.

In some aspects, the substrate core 753 may include a dielectric material with pre-impregnated reinforcement components embedded therein. In some aspects, the substrate core 753 may include prepreg (also known as PPG), which may include polymer resins with fiber glass sheets impregnated therein. In some aspects, the substrate core 753 includes at least one plated through hole (PTH) 756 disposed through the substrate core 753 configured to couple portions of the first metallization structure 751 and the second metallization structure 752 on opposite sides of the substrate core 753.

In some aspects, the first metallization structure 751 may comprise multiple layers of Ajinomoto build-up film (ABF) or similar other epoxy or resin based layers. In some aspects, the second metallization structure may comprise fiberglass impregnated with resin (prepreg), Ajinomoto build-up film (ABF), a resin coated copper (RCC) build-up film or any similar material. In some aspects, the metal layers and vias of the first metallization structure 751, the second metallization structure 752, PTH 756, and other conductive elements disclosed herein may comprise any highly conductive material, such as, copper (Cu), aluminum (AL), silver (Ag), gold (Au) titanium (+Ti), nickel (Ni), tin (Sn), lead (Pb), alloys or combinations thereof.

The lid 710 may be formed from a conductive (e.g., Cu or stainless steel) or non-conductive material (e.g., Silicon or Glass). In some aspects, the embedded lid support structure 760 may be configured to enclose all sides of the perimeter of the first metallization structure 751 and correspondingly enclosing the die 720. In other aspects, the embedded lid support structure 760 may be configured to enclose only a portion of the perimeter of the first metallization structure 751 and correspondingly only partially enclosing the die 720. In some aspects, the embedded lid support structure 760 may include a plurality of openings (not expressly illustrated). In some aspects, the plurality of openings can be configured to allow electrical traces to penetrate out from the enclosed portions of the first metallization structure 751.

It will be appreciated that the various materials discussed above are applicable to other similar elements disclosed herein (e.g., metallizations structures, substrate cores, lids, etc.). Further, it will be appreciated that the various aspects disclosed and claimed herein should not be interpreted to be limited to the specific example configurations illustrated and discussed.

In order to fully illustrate aspects of the design of the present disclosure, methods of fabrication are presented. Further, many details in the fabrication process known to those skilled in the art may have been omitted or combined in summary process portions to facilitate an understanding of the various aspects disclosed without a detailed rendition of each detail and/or all possible process variations. Other methods of fabrication are possible, and discussed fabrication methods are presented only to aid understanding of the concepts disclosed herein.

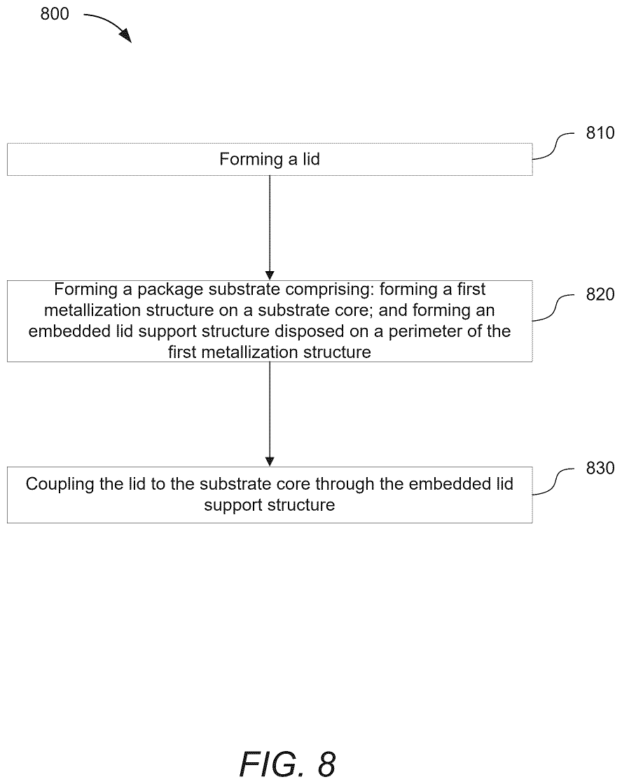

FIG. 8 illustrates a method 800 for manufacturing/fabricating and apparatus with a substrate with an embedded exposed lid (e.g., any of the example apparatuses 100 through 700), according to aspects of the disclosure. It will be appreciated from the foregoing that there are various methods for fabricating devices including an embedded exposed lid as disclosed herein.

At operation 810, the process includes forming a lid (e.g., 110, 210, 310, 410, 510, 610, or 710). The lid may completely or at least partially enclose dies and other components on the surface of the package substrate, as discussed herein.

At operation 820, the process includes forming a package substrate (e.g., 150, 250, 350, 450, 550, 650, and 750) comprising: forming a first metallization structure (e.g., 351, 451, 551, 651, and 751) on a substrate core (e.g., 353, 453, 553, 653, and 753); and forming an embedded lid support structure (e.g., 360, 460, 560, 660, and 760) disposed on a perimeter of the first metallization structure (e.g., 351, 451, 551, 651, and 751). In some aspects, it will be appreciated that forming the first metallization structure, and forming the embedded lid support structure, as part of operation 820, may be performed in parallel as each layer of the first metallization structure is fabricated.

At operation 830, the process includes coupling the lid (e.g., 110, 210, 310, 410, 510, 610, or 710) to the substrate core (e.g., 353, 453, 553, 653, and 753) through the embedded lid support structure (e.g., 360, 460, 560, 660, and 760). As discussed in the foregoing, in some aspects, the coupling can be performed by an adhesive bonding of the embedded lid support structure (e.g., extended lid foot) to the substrate core. In some aspects, the embedded lid support structure is fabricated directly on the substrate core and the coupling is performed by bonding the embedded lid support structure to the lid using an adhesive or a compliance material (e.g., an IMC).

It will be appreciated that the foregoing fabrication process was provided merely as general illustration of some of the aspects of the disclosure and is not intended to limit the disclosure or accompanying claims. Further, many details in the fabrication process known to those skilled in the art may have been omitted or combined in summary process portions to facilitate an understanding of the various aspects disclosed without a detailed rendition of each detail and/or all possible process variations.

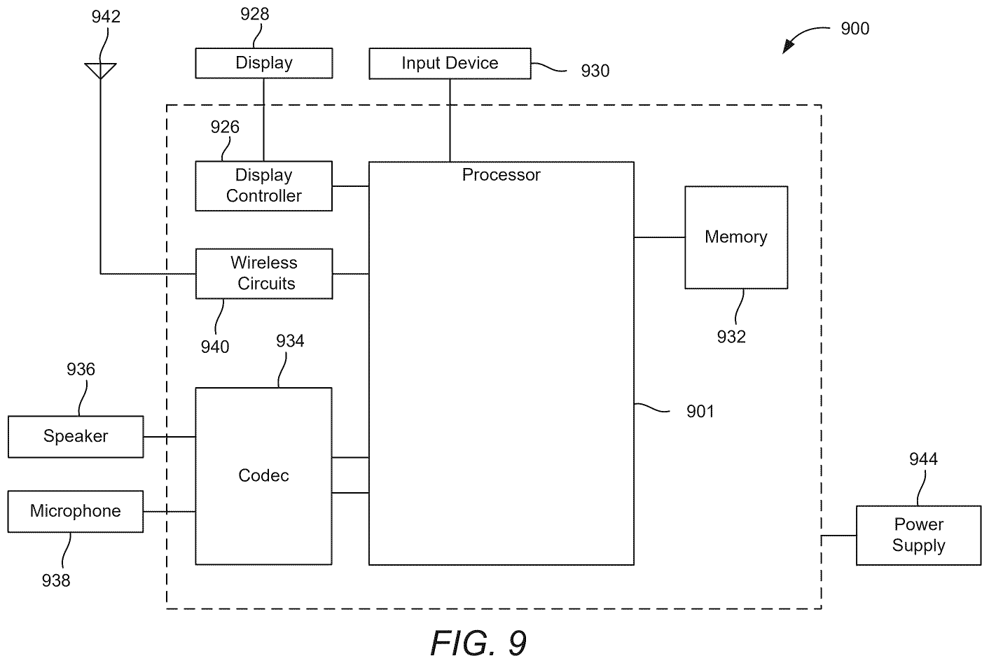

FIG. 9 illustrates a mobile device 900, according to aspects of the disclosure. In some aspects, the mobile device 900 may be implemented by including one or more IC devices including the hybrid substrate with embedded components as disclosed herein.

In some aspects, mobile device 900 may be configured as a wireless communication device. As shown, mobile device 900 includes processor 901. Processor 901 may be communicatively coupled to memory 932 over a link, which may be a die-to-die or chip-to-chip link. Mobile device 900 also includes display 928 and display controller 926, with display controller 926 coupled to processor 901 and to display 928. The mobile device 900 may include input device 930 (e.g., physical, or virtual keyboard), power supply 944 (e.g., battery), speaker 936, microphone 938, and wireless antenna 942. In some aspects, the power supply 944 may directly or indirectly provide the supply voltage for operating some or all of the components of the mobile device 900.

In some aspects, FIG. 9 may include coder/decoder (CODEC) 934 (e.g., an audio and/or voice CODEC) coupled to processor 901; speaker 936 and microphone 938 coupled to CODEC 934; and wireless circuits 940 (which may include a modem, RF circuitry, filters, etc.) coupled to wireless antenna 942 and to processor 901.

In some aspects, one or more of processor 901 (e.g., SoCs, application processor (AP), central processing unit (CPU), digital signal processor (DSP), etc.), display controller 926, memory 932, CODEC 934, and wireless circuits 940 (e.g., baseband interface) including IC devices that are packaged as IC packages and including substrates with an embedded exposed lid according to the various aspects described in this disclosure.

It should be noted that although FIG. 9 depicts a mobile device 900, similar architecture may be used to implement an apparatus including, a microprocessor, a server, a set top box, a music player, a video player, an entertainment unit, a navigation device, a personal digital assistant (PDA), a fixed location data unit, a computer, a laptop, a tablet, a communications device, a mobile phone, or other similar devices.

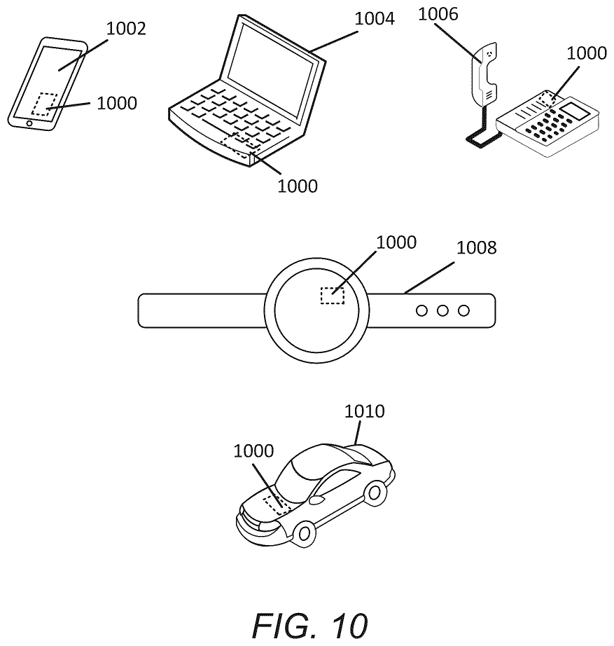

FIG. 10 illustrates various electronic devices that may be integrated with any of the aforementioned devices, semiconductor devices, integrated circuit (IC) packages, integrated circuit (IC) devices, electronic components, interposer packages, package-on-package (POP), System in Package (SiP), or System on Chip (SoC). For example, a mobile phone device 1002, a laptop computer device 1004, a fixed location terminal device 1006, a wearable device 1008, or automotive vehicle 1010 may include a semiconductor device 1000 (e.g., including embedded exposed lids) as described herein. The devices 1002, 1004, 1006 and 1008 and the vehicle 1010 illustrated in FIG. 10 are merely exemplary. Other apparatuses or devices may also feature the semiconductor device 1000 including, but not limited to, a group of devices that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

The devices illustrated in FIG. 10 are merely non-limiting examples. Other electronic devices may also feature the semiconductor devices as described in this disclosure, including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device, an access point, a base station, or any other device that stores or retrieves data or computer instructions or any combination thereof.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

One or more of the components, processes, features, and/or functions illustrated in FIGS. 1-10 may be rearranged and/or combined into a single component, process, feature, or function or incorporated in several components, processes, or functions. Additional elements, components, processes, and/or functions may also be added without departing from the disclosure. In some implementations, FIGS. 1-10 and the corresponding description may be used to manufacture, create, provide, and/or produce integrated devices. In some implementations, a device may include a die, an integrated device, a die package, an IC, a device package, an IC package, a wafer, a semiconductor device, a system in package (SiP), a system on chip (SoC), a package on package (POP) device, and the like.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. An apparatus comprising: a lid; a package substrate comprising: a first metallization structure; a substrate core; and an embedded lid support structure disposed on a perimeter of the first metallization structure, wherein the embedded lid support structure is configured to couple the lid to the substrate core.

Clause 2. The apparatus of clause 1, wherein the embedded lid support structure is an extended foot portion of the lid that is disposed in a cavity formed in the package substrate.

Clause 3. The apparatus of clause 2, wherein the embedded lid support structure is directly bonded to the substrate core.

Clause 4. The apparatus of any of clauses 1 to 3, wherein the embedded lid support structure is a conductive block disposed above the substrate core and in direct contact with the substrate core.

Clause 5. The apparatus of clause 4, wherein the embedded lid support structure is bonded to the lid with an adhesive.

Clause 6. The apparatus of any of clauses 1 to 5, wherein the embedded lid support structure comprises a plurality of vias and a plurality of metal layers of the first metallization structure arranged in a stacked configuration and in direct contact with the substrate core.

Clause 7. The apparatus of clause 6, wherein the embedded lid support structure is bonded to the lid with an adhesive.

Clause 8. The apparatus of any of clauses 6 to 7, wherein the embedded lid support structure is bonded to the lid with a compliance material.

Clause 9. The apparatus of clause 8, wherein the compliance material is an intermetallic compound (IMC).

Clause 10. The apparatus of any of clauses 1 to 9, wherein the embedded lid support structure comprises a plurality of openings.

Clause 11. The apparatus of any of clauses 1 to 10, wherein: the embedded lid support structure is configured to enclosing all sides of the perimeter of the first metallization structure, or the embedded lid support structure is configured to enclose only a portion of the perimeter of the first metallization structure.

Clause 12. The apparatus of any of clauses 1 to 11, further comprising: at least one die disposed on a top surface of the package substrate and electrically coupled to the first metallization structure of the package substrate;

Clause 13. The apparatus of any of clauses 1 to 12, further comprising: a second metallization structure disposed on a bottom side of the substrate core; and a plurality of connectors disposed on a bottom surface of the package substrate and electrically coupled to the second metallization structure of the package substrate.

Clause 14. The apparatus of any of clauses 1 to 13, wherein the apparatus comprises at least one of: a music player, a video player, an entertainment unit, a navigation device, a communications device, a mobile device, a mobile phone, a smartphone, a personal digital assistant, a fixed location terminal, a tablet computer, a computer, a wearable device, a laptop computer, a device in an automotive vehicle, an internet of things (IoT) device, or a server.

Clause 15. A method of manufacturing an apparatus, the method comprising: forming a lid; forming a package substrate comprising: forming a first metallization structure on a substrate core; and forming an embedded lid support structure disposed on a perimeter of the first metallization structure; and coupling the lid to the substrate core through the embedded lid support structure.

Clause 16. The method of clause 15, wherein forming the embedded lid support structure comprises: forming an extended foot portion of the lid; and disposing the extended foot portion of the lid in a cavity in the package substrate.

Clause 17. The method of any of clauses 15 to 16, wherein forming the embedded lid support structure comprises: forming a conductive block in the first metallization structure directly coupled to the substrate core.

Clause 18. The method of any of clauses 15 to 17, wherein forming the embedded lid support structure comprises: forming a plurality of vias and a plurality of metal layers of the first metallization structure in a stacked configuration in direct contact with the substrate core.

Clause 19. The method of clause 18, wherein coupling the lid to the substrate core comprises: bonding the embedded lid support structure to the lid with an adhesive.

Clause 20. The method of clause 18, wherein coupling the lid to the substrate core comprises: bonding the embedded lid support structure to the lid with a compliance material.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general-purpose processor, a DSP, an ASIC, an FPGA, or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

Furthermore, as used herein, the terms “set,” “group,” and the like are intended to include one or more of the stated elements. Also, as used herein, the terms “has,” “have,” “having,” “comprises,” “comprising,” “includes,” “including,” and the like does not preclude the presence of one or more additional elements (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”) or the alternatives are mutually exclusive (e.g., “one or more” should not be interpreted as “one and more”). Furthermore, although components, functions, actions, and instructions may be described or claimed in the singular, the plural is contemplated unless limitation to the singular is explicitly stated. Accordingly, as used herein, the articles “a,” “an,” “the,” and “said” are intended to include one or more of the stated elements. Additionally, as used herein, the terms “at least one” and “one or more” encompass “one” component, function, action, or instruction performing or capable of performing a described or claimed functionality and also “two or more” components, functions, actions, or instructions performing or capable of performing a described or claimed functionality in combination.

While the foregoing disclosure shows illustrative aspects of the disclosure, it should be noted that various changes and modifications could be made herein without departing from the scope of the disclosure as defined by the appended claims. For example, the functions, steps and/or actions of the method claims in accordance with the aspects of the disclosure described herein need not be performed in any particular order. Further, no component, function, action, or instruction described or claimed herein should be construed as critical or essential unless explicitly described as such.

What is claimed is:

1. An apparatus comprising:
a lid;
a package substrate comprising:
a first metallization structure;
a substrate core; and
an embedded lid support structure disposed on a perimeter of the first metallization structure, wherein the embedded lid support structure is configured to couple the lid to the substrate core.

2. The apparatus of claim 1, wherein the embedded lid support structure is an extended foot portion of the lid that is disposed in a cavity formed in the package substrate.

3. The apparatus of claim 2, wherein the embedded lid support structure is directly bonded to the substrate core.

4. The apparatus of claim 1, wherein the embedded lid support structure is a conductive block disposed above the substrate core and in direct contact with the substrate core.

5. The apparatus of claim 4, wherein the embedded lid support structure is bonded to the lid with an adhesive.

6. The apparatus of claim 1, wherein the embedded lid support structure comprises a plurality of vias and a plurality of metal layers of the first metallization structure arranged in a stacked configuration and in direct contact with the substrate core.

7. The apparatus of claim 6, wherein the embedded lid support structure is bonded to the lid with an adhesive.

8. The apparatus of claim 6, wherein the embedded lid support structure is bonded to the lid with a compliance material.

9. The apparatus of claim 8, wherein the compliance material is an intermetallic compound (IMC).

10. The apparatus of claim 1, wherein the embedded lid support structure comprises a plurality of openings.

11. The apparatus of claim 1, wherein:
the embedded lid support structure is configured to enclose all sides of the perimeter of the first metallization structure, or
the embedded lid support structure is configured to enclose only a portion of the perimeter of the first metallization structure.

12. The apparatus of claim 1, further comprising:
at least one die disposed on a top surface of the package substrate and electrically coupled to the first metallization structure of the package substrate.

13. The apparatus of claim 1, further comprising:
a second metallization structure disposed on a bottom side of the substrate core; and
a plurality of connectors disposed on a bottom surface of the package substrate and electrically coupled to the second metallization structure of the package substrate.

14. The apparatus of claim 1, wherein the apparatus comprises at least one of: a music player, a video player, an entertainment unit, a navigation device, a communications device, a mobile device, a mobile phone, a smartphone, a personal digital assistant, a fixed location terminal, a tablet computer, a computer, a wearable device, a laptop computer, a device in an automotive vehicle, an internet of things (IoT) device, or a server.

15. A method of manufacturing an apparatus, the method comprising:
forming a lid;
forming a package substrate comprising:
forming a first metallization structure on a substrate core; and
forming an embedded lid support structure disposed on a perimeter of the first metallization structure; and
coupling the lid to the substrate core through the embedded lid support structure.

16. The method of claim 15, wherein forming the embedded lid support structure comprises:
forming an extended foot portion of the lid; and
disposing the extended foot portion of the lid in a cavity in the package substrate.

17. The method of claim 15, wherein forming the embedded lid support structure comprises:
forming a conductive block in the first metallization structure directly coupled to the substrate core.

18. The method of claim 15, wherein forming the embedded lid support structure comprises:
forming a plurality of vias and a plurality of metal layers of the first metallization structure in a stacked configuration in direct contact with the substrate core.

19. The method of claim 18, wherein coupling the lid to the substrate core comprises:
bonding the embedded lid support structure to the lid with an adhesive.

20. The method of claim 18, wherein coupling the lid to the substrate core comprises:
bonding the embedded lid support structure to the lid with a compliance material.
